(19) United States
(12) Patent Application Publication
(10) Pub. No.: US 2020/0258929 A1
(43) Pub. Date: Aug. 13, 2020

(54) SOLID-STATE IMAGING DEVICE AND METHOD OF MANUFACTURING THE SAME

(71) Applicant: TOPPAN PRINTING CO., LTD., Taito-ku (JP)

(72) Inventors: Tomohiro IMOTO, Taito-ku (JP); Satoshi TAKAHASHI, Taito-ku (JP)

(73) Assignee: TOPPAN PRINTING CO., LTD., Taito-ku (JP)

(21) Appl. No.: 16/861,580

(22) Filed: Apr. 29, 2020

Related U.S. Application Data
(63) Continuation of application No. PCT/JP2018/037024, filed on Oct. 3, 2018.

(30) Foreign Application Priority Data
Nov. 1, 2017 (JP) 2017-211778

(51) Int. Cl. H01L 27/146; H01L 21/311; H04N 9/04

(52) U.S. Cl. CPC H01L 27/14621; H01L 27/14627; H04N 9/0451; H01L 27/14667; H01L 21/31138; H01L 27/14685

(57) ABSTRACT

A solid-state imaging device including a semiconductor substrate having photoelectric conversion elements, a color filter layer having color filters of multiple colors, a partition wall, and a transparent resin layer. A thickness A of a color filter of a first color, a thickness B of the transparent resin layer, a thickness C of a color filter of a color other than the first color, a visible light transmittance D of the transparent resin layer, and a dimension E of the partition wall satisfy formulas (1) to (5):

200 nm≤A≤700 nm (1);

0 nm<B≤200 nm (2);

A+B−200 nm≤C≤A+B+200 nm (3);

D≥90% (4); and

E≤200 nm (5).

### CROSS-REFERENCE TO RELATED APPLICATIONS

The present application is a continuation of International Application No. PCT/JP2018/037024, filed Oct. 3, 2018, which is based upon and claims the benefits of priority to Japanese Application No. 2017-211778, filed Nov. 1, 2017. The entire contents of all of the above applications are incorporated herein by reference.

### BACKGROUND OF THE INVENTION

### Field of the Invention

The present invention relates to a solid-state imaging device and a method of manufacturing the same.

### Discussion of the Background

In recent years, solid-state imaging devices such as CCD (charge-coupled device) and CMOS (complementary metal-oxide semiconductor) sensors mounted in digital cameras and the like have a higher number of pixels of a smaller size. Particularly small solid-state imaging devices have a pixel size smaller than 1.4 μm×1.4 μm.

Solid-state imaging devices for generating color images include photoelectric conversion elements arranged for respective pixels and a color filter layer having a predetermined color pattern. Further, solid-state imaging devices have regions (openings) in which the photoelectric conversion elements contribute to photoelectric conversion. These regions (openings) depend on the size and the number of pixels of the solid-state imaging device. The area of the openings is limited to approximately 20 to 50% of the total area of the solid-state imaging device. Since smaller openings directly lead to lower sensitivity of the photoelectric conversion elements, solid-state imaging devices generally include microlenses for focusing light on the photoelectric conversion elements to compensate for the lower sensitivity.

Recently, there have been developed image sensors using a backside-illumination technology with which the area of the openings of the photoelectric conversion elements is increased to 50% or more of the total area of the solid-state imaging device. In this case, however, light leaking from a color filter may enter an adjacent color filter. Therefore, formation of microlenses having an appropriate size and shape is required.

As described in PTL 1, a color filter layer having a predetermined pattern is typically formed by patterning color filters of respective colors by a photolithography process.

Further, PTL 2 describes another patterning method, by which a color filter layer of a first color is patterned by dry etching on a solid-state imaging device, and color filter layers of second and subsequent colors are patterned by photolithography.

Still further, PTL 3 describes a method of patterning color filters of all colors by dry etching.

Recently, there is an increasing need of high-definition CCD imaging devices having more than 8,000,000 pixels, entailing an increasing need of such high-definition imaging devices having color filter patterns conforming to a pixel size of less than 1.4 μm×1.4 μm. However, a smaller pixel size leads to insufficient resolution of a color filter patterned by photolithography, which causes a problem of adversely affecting characteristics of the solid-state imaging device. In a solid-state imaging device having a pixel size of 1.4 μm square or less, or of close to 1.1 μm or 0.9 μm square, insufficient resolution performance results in color unevenness caused by pattern shape defects.

Furthermore, a smaller pixel size leads to a larger aspect ratio of a pattern of a color filter layer (a thickness of the pattern of the color filter layer becomes larger relative to a width of the pattern of the color filter layer). When such a color filter layer is formed by patterning by photolithography, portions originally to be removed (ineffective portions of pixels) are not completely removed and remain as residues, and adversely affect pixels of other colors. When measures such as extension of development time are taken to remove the residues, another problem occurs that pixels which have been cured and are necessary may also be removed.

Moreover, in order to obtain satisfactory spectral characteristics, color filters need to have a larger thickness. However, as the thickness of the color filters increases, the corners of the patterned color filters become rounded with pixel miniaturization, which causes a decrease in resolution. When the color filters have an increased thickness to obtain desired spectral characteristics, the pigment concentration (concentration of a colorant) in the color filter material needs to be increased. However, when the pigment concentration is increased, light necessary for a photo-curing reaction may not reach the bottom of the color filter layer, leading to insufficient curing of the color filter layer. This causes a problem that the color filter layer peels off at a development step during photolithography, and pixel defects occur.

When the color filters have a smaller thickness, and a pigment concentration in a color filter material is increased to obtain desired spectral characteristics, the amount of a photo-curable component is relatively reduced. This leads to insufficient photo-curing of the color filter layer. As a consequence, deterioration in shape, uneven planarity, shape deformation, and the like are more likely to occur. Furthermore, when an exposure amount in curing is increased to obtain sufficient photo-curing, a problem of reduction in throughput occurs.

Due to the very fine patterns of the color filter layer, a thickness of the color filter layer not only causes a problem in the manufacturing process but also influences the characteristics of the solid-state imaging device. When the color filter layer has a large thickness, light that is obliquely incident and dispersed by a color filter of a specific color may then enter an adjacent filter pattern portion of another color and the photoelectric conversion element under the filter pattern portion. In this case, a color mixture problem occurs. The color mixture problem becomes apparent as the pixel size becomes smaller and the aspect ratio between the pixel size defining a pattern size and the thickness of the color filter becomes larger. Furthermore, a problem regarding color mixture of incident light also becomes apparent when a distance between a color filter pattern and the photoelectric conversion elements increases due to formation of a material for a transparent resin layer and the like on a substrate in which photoelectric conversion elements are provided. Accordingly, it is important to reduce the thickness of the color filter layer, the transparent resin layer formed under the color filter layer, and the like.

In a known method of preventing color mixture due to entry of light from a direction oblique to pixels, partition walls are provided between the color filters of respective colors to block the light. Color filters for optical display devices such as liquid crystal displays use generally known partition walls of a black matrix structure (BM) made of a black material. However, solid-state imaging devices include color filter patterns with a size of several micrometers or less. Therefore, if partition walls are formed by a generally used method of forming a black matrix, pixels are partially filled with BM, causing pixel defects and lower resolution, because the pattern size is large. In the case of solid-state imaging devices of advanced high definition, the partition walls need to have a size of several hundred nanometers, more preferably, a dimension of approximately 200 nm or less. That is, high definition of pixels has already advanced to such an extent that the pixel size is approximately 1 μm. Therefore, if the partition wall is able to reduce or prevent color mixture, the thickness is desirably 100 nm or less. The partition wall of this size is difficult to produce by photolithography using BM. For this reason, another method can be adopted to form a partition wall, which includes film formation by using an inorganic material such as metal or SiO₂ by dry etching, vapor deposition, sputtering, or the like, and etching to form a grid pattern. However, such a method entails very high manufacturing cost due to complication of the manufacturing apparatus, the manufacturing process, or the like.

Thus, in order to increase the number of pixels in a solid-state imaging device, color filter layer patterns are required to have a higher definition, and thus thinning of the color filter layer and prevention of color mixture are of importance.

As mentioned above, in the conventional pattern formation of a color filter layer formed of a photosensitive color filter material by photolithography, a smaller pixel size requires the color filter layer to have a smaller thickness. In this case, since a ratio of a pigment component in the color filter material is increased, the color filter material fails to contain a sufficient amount of photosensitive component. This causes problems in that desired resolution performance cannot be obtained, residues are more likely to remain, and pixels are more likely to peel off, leading to deterioration of characteristics of the solid-state imaging device.

Therefore, in order to achieve a finer and thinner pattern of a color filter layer, the techniques of PTLs 2 and 3 have been proposed. In PTLs 2 and 3, in order to increase a pigment concentration in a color filter material, color filters of a plurality of colors are formed by patterning by dry etching, which enables patterning without using a photosensitive component. These techniques using dry etching can increase a pigment concentration, and make it possible to fabricate a color filter pattern that achieves sufficient spectral characteristics even when the color filter pattern is reduced in thickness.

PTL 1: JP H11-68076 A

PTL 2: JP 4857569 B

PTL 3: JP 4905760 B

### SUMMARY OF THE INVENTION

According to an aspect of the present invention, a solid-state imaging device includes a semiconductor substrate having photoelectric conversion elements formed two-dimensionally therein, a color filter layer formed on the semiconductor substrate and having color filters of multiple colors formed two-dimensionally in a preset regular pattern corresponding to the photoelectric conversion elements, a partition wall formed between the color filters of the multiple colors, and a transparent resin layer formed between the semiconductor substrate and a color filter of a first color among the multiple colors. The color filters, the transparent resin layer, and the partition wall satisfy formulas (1)-(5):

200≤A≤700 (1)

0<B≤200 (2)

A+B−200≤C≤A+B+200 (3)

D≥90 (4)

E≤200 (5)

where A is a thickness, in nm, of the color filter of the first color, B is a thickness, in nm, of the transparent resin layer, C is a thickness, in nm, of a color filter of a color other than the first color, D is a visible light transmittance, in %, of the transparent resin layer, and E is a dimension in a width direction, in nm, of the partition wall.

According to another aspect of the present invention, a method for producing a solid-state imaging device includes forming a transparent resin layer on a semiconductor substrate having photoelectric conversion elements being formed two-dimensionally therein, applying a coating liquid for a color filter of a first color among multiple colors, curing the coating liquid such that a color filter curing layer is formed on the transparent resin layer, removing by dry etching a first removal target region in the color filter curing layer, which is a region other than a portion for the color filter of the first color, and a second removal target region in the transparent resin layer, which is a region under the first removal target region in the color filter curing layer, such that a color filter of the first color is formed and patterned on the semiconductor substrate, forming a partition wall from a by-product of a reaction of a dry etching gas with the color filter curing layer and the transparent resin layer which are removed by the dry etching, and forming a color filter of a color other than the first color by photolithography at a position where the color filter curing layer and the transparent resin layer have been removed such that color filters of the multiple colors are formed, with the partition wall formed therebetween, in a preset regular pattern corresponding to the photoelectric conversion elements. The removing of the second removal target region removes either an entirety of the second removal target region or a portion of the second removal target region which faces the color filter layer, in a thickness direction of the second removal target region.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1(a)-FIG. 1(d) are cross-sectional views of a solid-state imaging device according to a first embodiment of the present invention.

FIG. 2 is a partial plan view of a color filter array according to the first embodiment of the present invention.

FIG. 3(a)-FIG. 3(g) are cross-sectional views illustrating a sequence of steps in application of a first-color color filter pattern and formation of openings at positions where second-color and subsequent color filters are to be formed by using a photosensitive resin pattern according to the first embodiment of the present invention.

FIG. 4(a) and FIG. 4(b) are cross-sectional views illustrating a sequence of steps in a process of fabricating a first-color color filter pattern by dry etching according to the first embodiment of the present invention.

FIG. 5(a)-FIG. 5(f) are cross-sectional views illustrating a sequence of steps in a process of fabricating second and third-color color filter patterns by photolithography according to the first embodiment of the present invention.

FIG. 6(a) and FIG. 6(b) are cross-sectional views illustrating a sequence of steps in a process of fabricating microlenses according to the first embodiment of the present invention.

FIG. 7(a)-FIG. 7(d) are cross-sectional views illustrating a sequence of steps in a process of fabricating microlenses by a transfer method using etchback according to the first embodiment of the present invention.

FIG. 8(a)-FIG. 8(d) are cross-sectional views illustrating a sequence of steps in a process of fabricating a first-color color filter pattern according to a second embodiment of the present invention.

FIG. 9(a)-FIG. 9(e) are cross-sectional views illustrating a sequence of steps in a process of fabricating a first-color color filter pattern according to a third embodiment of the present invention.

### DESCRIPTION OF THE EMBODIMENTS

The embodiments will now be described with reference to the accompanying drawings, wherein like reference numerals designate corresponding or identical elements throughout the various drawings.

An embodiment of the present invention will be described below with reference to the drawings. Here, the drawings are schematic, and the relationship between the thickness and planar dimensions, the ratios of the thicknesses of each layer, and the like, are different from actual ones. Furthermore, the embodiments described below show, as examples, configurations for embodying a technical idea of the present invention. The technical idea of the present invention does not specify materials, shapes, structures, or the like of components as below. The technical idea of the present invention may be altered in various manners within the scope of the claims.

### First Embodiment

### <Configuration of Solid-State Imaging Device>

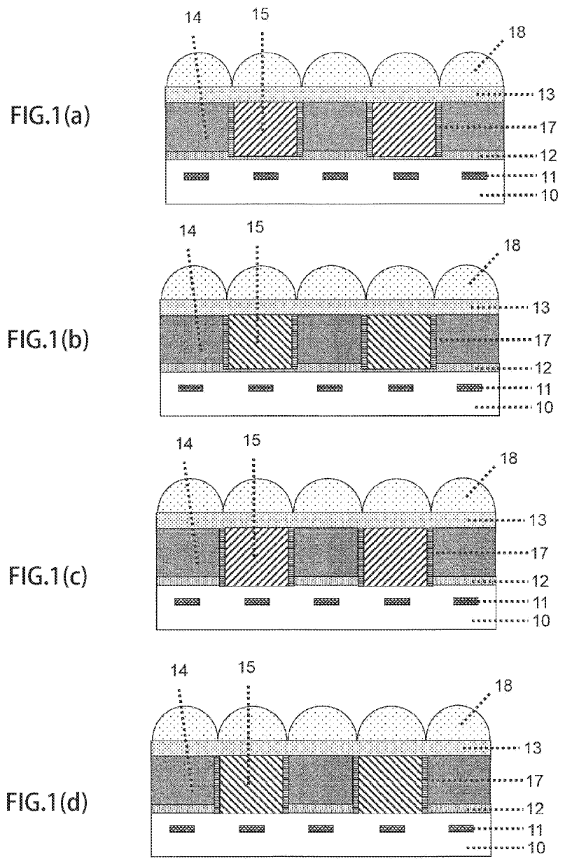

As shown in FIGS. 1(a) to 1(d), a solid-state imaging device according to the present embodiment includes a semiconductor substrate 10 including a plurality of photoelectric conversion elements 11 that are two-dimensionally arranged, a microlens group composed of a plurality of microlenses 18 that are arranged above the semiconductor substrate 10, and a color filter layer and partition walls 17 provided between the semiconductor substrate 10 and the microlenses 18. The color filter layer is composed of color filters 14, 15, and 16 of a plurality of colors, which are two-dimensionally arranged in a predetermined regular pattern. The partition wall 17 are each disposed between the color filters 14, 15, and 16 of the plurality of colors.

FIGS. 1(a) and 1(b) illustrate a configuration in which a transparent resin layer 12 provided under second and third-color color filters is thinner than a transparent resin layer 12 provided under a first-color color filter. FIGS. 1(c) and 1(d) illustrate a configuration in which a transparent resin layer 12 is provided under the first-color color filter but is not provided under the second and third-color color filters.

Furthermore, a flattening layer 13 is provided between the color filter layer and the microlens group composed of the plurality of microlenses 18.

In the following description of the solid-state imaging device according to the present embodiment, a color filter first formed in a manufacturing process and having a largest occupation area is defined as a first-color color filter 14. Further, a color filter secondly formed in the manufacturing process is defined as a second-color color filter 15, and a color filter thirdly formed in the manufacturing process is defined as a third-color color filter 16. This also applies to other embodiments.

In the solid-state imaging device according to the present embodiment, the first-color color filter 14 includes a thermosetting resin and a photo-curable resin (hereinafter, also referred to as a “photosensitive resin”). The content of the photo-curable resin is lower than the content of the thermosetting resin.

The first-color color filter 14 may not be necessarily a color filter having a largest occupation area or a color filter formed first.

In the present embodiment, the color filter layer is illustrated as being configured such that the plurality of colors are composed of three colors, i.e., green, blue, and red, and are arranged in an arrangement pattern of a Bayer array. However, the color filter layer may also be composed of color filters of four or more colors.

In the following description, the first color is assumed to be green, but the first color may be blue or red.

Components of the solid-state imaging device will now be described in detail.

### (Photoelectric Conversion Elements and Semiconductor Substrate)

In the semiconductor substrate 10, the plurality of photoelectric conversion elements 11 are two-dimensionally arranged corresponding to respective pixels. The photoelectric conversion elements 11 each have a function of converting light into an electrical signal.

For the purpose of protecting and flattening a surface (light incident surface) of the semiconductor substrate 10 in which the photoelectric conversion elements 11 are formed, a protective film is typically provided on an outermost surface of the semiconductor substrate 10. The semiconductor substrate 10 is made of a material that transmits visible light and can withstand a temperature of at least approximately 300° C. Examples of such a material include Si-containing materials, including Si, an oxide such as SiO₂, a nitride such as SiN, and a mixture thereof.

### (Microlenses)

The microlenses 18 are arranged above the semiconductor substrate 10 corresponding to the respective pixel positions. Specifically, the microlenses 18 are provided for the respective photoelectric conversion elements 11 two-dimensionally arranged in the semiconductor substrate 10. The microlenses 18 focus light that is incident on the microlenses 18 onto the respective photoelectric conversion elements 11 to compensate for the lower sensitivity of the photoelectric conversion elements 11.

A height from a lens top to a lens bottom of the microlens 18 is preferably in the range of 300 nm or more and 800 nm or less. When the height from a lens top to a lens bottom is smaller than 300 nm, the lens is too small to collect sufficient light, which causes a lower light receiving sensitivity. When the height from a lens top to a lens bottom is larger than 800 nm, a light collecting position of light collected by the lens is too high and deviated from the typical light collecting position, which causes a lower light receiving sensitivity.

### (Transparent Resin Layer)

The transparent resin layer 12 is provided to protect and flatten the surface of the semiconductor substrate 10. Specifically, the transparent resin layer 12 reduces asperities on the upper surface of the semiconductor substrate 10 caused by fabrication of the photoelectric conversion elements 11, and improves adhesion to a color filter material.

In the present embodiment, a part (a portion facing the color filter layer) or the entirety of the transparent resin layer 12 is removed in the thickness direction at positions other than under the first-color color filter 14 by dry etching, which will be described later.

The transparent resin layer 12 is made of, for example, a resin containing one or more resins such as an acrylic resin, an epoxy-based resin, a polyimide-based resin, a phenol novolak-based resin, a polyester-based resin, a urethane-based resin, a melamine-based resin, a urea-based resin, a styrene-based resin, and a silicon-based resin. The material for the transparent resin 12 is not limited to these resins. Any material may be used as long as it transmits visible light having a wavelength in the range from 400 nm to 700 nm and does not hinder patterning and adhesion of the color filters 14, 15, and 16.

Further, the transparent resin 12 is preferably made of a resin that does not affect spectral characteristics of the color filters 14, 15, and 16. For example, the transparent resin layer 12 is preferably formed to have a transmittance D of 90% or more to visible light having a wavelength in the range from 400 nm to 700 nm.

The transparent resin layer 12 preferably has a refractive index F in the range of larger than 1.4 and smaller than 1.65. When the refractive index of a transparent resin material is smaller than 1.4 or larger than 1.65, reflection is more likely to occur due to an increased difference in refractive index from an oxide film layer, which is a surface layer of a typical semiconductor substrate. Accordingly, the refractive index of the transparent resin layer 12 is preferably larger than 1.4 and smaller than 1.65. The transparent resin material having such a refractive index is made of materials described above. For example, a silicon-based resin is a compound containing silicon and oxygen in a main chain, and has a refractive index of 1.41.

In the present embodiment, the transparent resin layer 12 is formed to have a thickness B [nm] in the range of larger than 0 [nm] and 200 [nm] or less. From the viewpoint of color mixture prevention, a transparent resin layer 12 having a smaller thickness B is more preferable.

### (Flattening Layer)

The flattening 13 is provided to planarize the upper surfaces of the color filters 14, 15, and 16, and the partition wall 17.

The flattening layer 13 is made of, for example, a resin containing one or more resins such as an acrylic resin, an epoxy-based resin, a polyimide-based resin, a phenol novolak-based resin, a polyester-based resin, a urethane-based resin, a melamine-based resin, a urea-based resin, a styrene-based resin, and a silicon-based resin. Further, the flattening layer 13 may also be integrated with the microlenses 18.

The flattening layer 13 has a thickness of, for example, 1 [nm] or more and 300 [nm] or less. From the viewpoint of color mixture prevention, a smaller thickness is more preferable.

### (Color Filters)

The color filters 14, 15, and 16 constituting the color filter layer in a predetermined pattern are filters that correspond to the respective colors for color separation of incident light. The color filters 14, 15, and 16 are provided between the semiconductor substrate 10 and the microlenses 18, and are arranged according to the respective pixel positions so as to correspond to the respective photoelectric conversion elements 11 in a preset regular pattern.

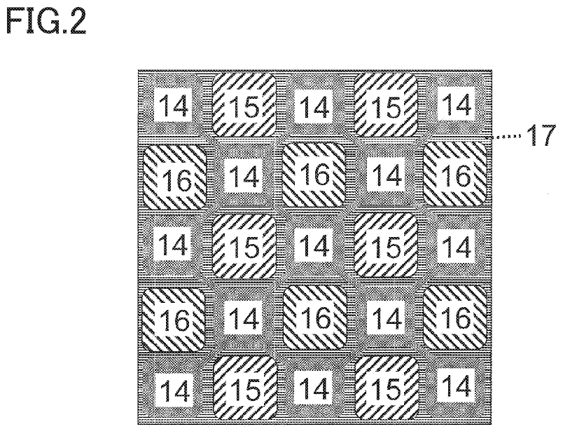

FIG. 2 is a plan view illustrating the color filters 14, 15, and 16 of the respective colors and an array of the partition walls 17 formed between the color filters 14, 15, and 16. The array shown in FIG. 2 is a Bayer array, and is formed by laying patterns of square color filters 14, 15, and 16 (first, second and third-color color filters) each having four rounded corners.

The color filters 14, 15, and 16 each contain a pigment (colorant) of a predetermined color and a thermosetting component and/or a photo-curable component. For example, the color filter 14 contains a green pigment, the color filter 15 contains a blue pigment, and the color filter 16 contains a red pigment as the colorant.

In the present embodiment, the color filters 14, 15, and 16 contain the thermosetting resin and the photo-curable resin. Preferably, the content of the thermosetting resin is higher than that of the photo-curable resin. In this case, for example, a curable component in a solid content is in the range of 5% by mass or more and 40% by mass or less, in which the thermosetting resin is in the range of 5% by mass or more and 20% by mass or less, and the photo-curable resin is in the range of 1% by mass or more and 20% by mass or less. Preferably, the thermosetting resin is in the range of 5% by mass or more and 15% by mass or less, and the photo-curable resin is in the range of 1% by mass or more and 10% by mass or less.

When the curable component is composed of only the thermosetting component, the curable component in the solid content is in the range of 5% by mass or more and 40% by mass or less, and more preferably in the range of 5% by mass or more and 15% by mass or less. On the other hand, when the curable component is composed of only the photo-curable component, the curable component in the solid content is in the range of 10% by mass or more and 40% by mass or less, and more preferably in the range of 10% by mass or more and 20% by mass or less.

### (Partition Walls)

The partition wall 17 are each disposed between the color filters 14, 15, and 16 of the plurality of colors. In the present embodiment, the partition wall 17 provided on the side wall of the first-color color filter 14 separates the first-color color filter 14 from the second and third-color color filters 15 and 16.

The partition wall 17 includes a by-product generated by reaction of a first-color color filter material contained in the first-color color filter 14 and a transparent resin material contained in the transparent resin layer 12, with a dry etching gas used in formation of the first-color color filter 14. When the first color is green (G) and the transparent resin layer 12 is made of a silicon-based resin, the first-color color filter material (green filter material) contains zinc, copper, nickel, bromine, and chlorine, whereas the transparent resin material contains silicon, and oxygen. These materials can be dry etched with a mixed gas containing oxygen. Accordingly, the partition wall 17 contains at least one selected from the group consisting of zinc, copper, nickel, bromine, chlorine, silicon, and oxygen.

In the present embodiment, the description will be given of the solid-state imaging device including the color filters in the Bayer array illustrated in FIG. 2. However, the array of the color filters of the solid-state imaging device are not necessarily limited to a Bayer array, and the colors of the color filters are not limited to the three RGB colors. Furthermore, a transparent layer having an adjusted refractive index may also be arranged in part of the color filter array.

The first-color color filter 14 is formed to have a thickness A [nm] in the range of 200 [nm] or more and 700 [nm] or less. Preferably, the thickness A [nm] is in the range of 400 [nm] or more and 600 [nm] or less. More preferably, the thickness A [nm] is 500 [nm] or less.

Further, the color filters 15 and 16 of colors other than the first color are each formed to have a thickness that satisfies the following formula:

A+B−200 [nm]≤C≤A+B+200 [nm]

where C [nm] is the thickness of the color filters 15 and 16.

However, the thickness of the second-color color filter 15 may differ from the thickness of the third-color color filter 16.

Here, the reason that the difference between the thickness (A+B) and the thickness C is set to be 200 [nm] or less is that, if the difference in the thickness exceeds 200 [nm] at a certain portion, light receiving sensitivity may be reduced due to the influence of light obliquely incident on another pixel. Furthermore, if a level difference exceeding 200 [nm] is present, it may be difficult to form the microlenses 18 above the color filters.

In order to achieve a thin color filter layer, a concentration of the pigment (colorant) contained in the first, second, and third-color color filters 14, 15, and 16 is preferably 50% by mass or more.

Furthermore, the partition walls 17 are respectively formed between the color filters 14, 15, and 16 of the plurality of colors. The partition wall 17 has a dimension E of 200 nm or less. The reason that the partition wall 17 is 200 nm or less is that, if the partition wall is larger than 200 nm, light incident on the photoelectric conversion elements 11 will be greatly reduced by the partition wall, which may cause reduction in light receiving sensitivity.

### <Method of Manufacturing Solid-State Imaging Device>

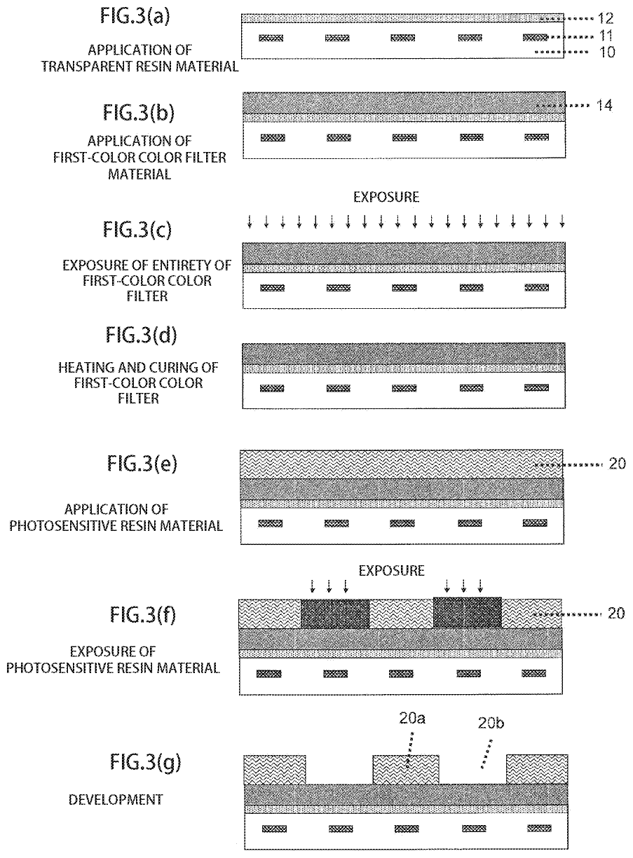

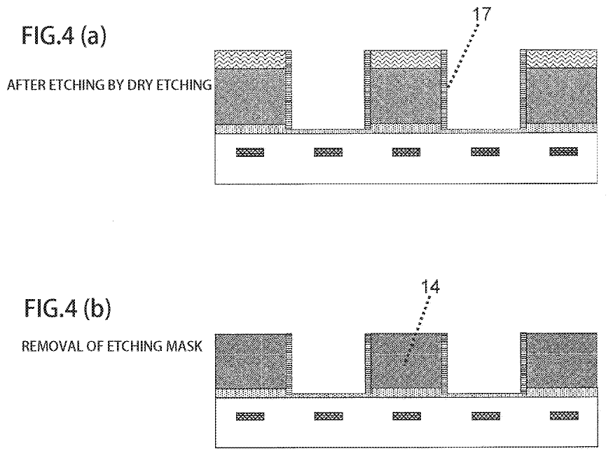

With reference to FIGS. 3(a) to 3(g) and 4(a) and 4(b), a method of manufacturing the solid-state imaging device of the first embodiment will be described.

### (Formation of Transparent Resin Layer)

As shown in FIG. 3(a), the semiconductor substrate 10 including the plurality of photoelectric conversion elements 11 is prepared, and the transparent resin layer 12 is formed on the entire surface of the semiconductor substrate 10 on which the filter layer is to be formed. The transparent resin layer 12 is made of, for example, a resin containing one or more of the resin materials such as a silicon-based resin described above, or a compound such as an oxide compound or a nitride compound.

The transparent resin layer 12 is formed by a method in which a coating liquid containing the resin material described above is applied and heated for curing. The transparent resin layer 12 may also be formed by forming a film of the compound described above by various methods such as vapor deposition, sputtering, and CVD.

The method of manufacturing the solid-state imaging device according to the present embodiment differs from a conventional method of manufacturing a solid-state imaging device by directly patterning the color filters 14, 15, and 16 constituting the color filter layer by photolithography using a photosensitive color filter material.

That is, in the method of manufacturing the solid-state imaging device according to the present embodiment, a coating liquid for forming the first-color color filter 14 is applied and cured on the entire surface of the transparent resin layer 12 to form a color filter curing layer which serves as a base of the first-color color filter 14 (see FIG. 3(d)). Then, portions of the color filter curing layer which correspond to portions where the color filters 15 and 16 of the other colors are to be formed (that is, a removal target region in the color filter curing layer, which is a region other than the arrangement position of the first-color color filter 14) are removed by dry etching. Thus, a pattern of the first-color color filter 14 (see FIG. 4(b)) is formed.

In dry etching, the transparent resin layer 12 is removed together with the removal target region of the color filter curing layer. That is, a part of the removal target region in the transparent resin layer 12 in the thickness direction, which underlies the removal target region in the color filter curing layer (only a portion facing the color filter layer) or the entirety thereof is removed by dry etching.

Further, the partition walls 17 between the color filters of the plurality of colors are formed from a by-product generated by the reaction of the color filter curing layer and the transparent resin layer 12 with a dry etching gas, in dry etching of the color filter curing layer and a part or the entirety of the transparent resin layer 12. Then, the second-color and subsequent color filters (second and third-color color filters 15 and 16) are patterned at portions surrounded by the first-color color filters 14 and the partition walls 17.

Here, the pattern of the first-color color filters 14 and the partition walls 17 formed earlier are used as a guide pattern to cure the second-color and subsequent color filter materials by heat treatment at a high temperature. Accordingly, even if the transparent resin layer 12 is not present under the second-color and subsequent color filters (second and third-color color filters 15 and 16), it is possible to improve adhesiveness between the semiconductor substrate 10 and the second-color and subsequent color filters (second and third-color color filters 15 and 16).

A step of forming the color filters will be described below.

### (Step of Forming First-Color Color Filter Layer (First Step))

First, as shown in FIGS. 3(b) to 3(d), a step of forming the first-color color filter 14 on a surface of the transparent resin layer 12 formed on the semiconductor substrate 10 will be described. The first-color color filter 14 is preferably a color filter that occupies a largest area in the solid-state imaging device.

As shown in FIG. 3(b), a first-color color filter material made of a first resin dispersion whose main component is a resin material and in which a first pigment (colorant) is dispersed is applied to the surface of the transparent resin layer 12 formed on the semiconductor substrate 10 in which the plurality of photoelectric conversion elements 11 are two-dimensionally arranged. As shown in FIG. 2, the solid-state imaging device of the present embodiment is assumed to use color filters arranged in a Bayer array. For this reason, the first color is preferably green (G).

The resin material of the first-color color filter material is a mixed resin containing a thermosetting resin such as an epoxy resin and a photo-curable resin such as an ultraviolet curable resin. The content of the photo-curable resin is set to be lower than that of the thermosetting resin. Since a larger amount of thermosetting resin is used as the resin material, a high content percentage of pigment in the first-color color filter 14 can be achieved, unlike a case where a larger amount of photo-curable resin is used as a curable resin. This facilitates formation of a thin first-color color filter 14 with desired spectral characteristics.

The present embodiment will be described by using a mixed resin containing both the thermosetting resin and the photo-curable resin. However, this is merely an example, and a resin containing only one of these curable resins may also be used.

Next, as shown in FIG. 3(c), the entire surface of the applied first-color color filter material is irradiated with ultraviolet light for photo-curing of the first-color color filter material. In the present embodiment, unlike the case where a color filter material is imparted with photosensitivity and exposed to directly form desired patterns as in the conventional art, the applied first-color color filter material is cured across the entirety of the surface thereof. Therefore, it can be cured even when the content of the photosensitive component is reduced.

Next, as shown in FIG. 3(d), the applied first-color color filter material is thermoset at a temperature of 150° C. or more and 300° C. or less to form a color filter curing layer. More specifically, the temperature is preferably 170° C. or more and 270° C. or less. In the manufacture of a solid-state imaging device, a high temperature heating step at a temperature of 100° C. or more and 300° C. or less is very often used during formation of the microlenses 18. Accordingly, the first-color color filter material desirably has high temperature resistance. For this reason, a thermosetting resin having high-temperature resistance is more preferred as a resin material.

Next, as shown in FIGS. 3(e) to 3(g), an etching mask pattern having an opening is formed on the color filter curing layer formed at the previous step.

First, as shown in FIG. 3(e), a photosensitive resin material is applied to the surface of the color filter curing layer and dried to form an etching mask 20.

Next, as shown in FIG. 3(f), the photosensitive resin film is exposed by using a photomask (not shown) to cause a chemical reaction so that a portion other than a necessary pattern becomes soluble in a developing solution.

Next, as shown in FIG. 3(g), unwanted portions (exposed portions) of the etching mask 20 are removed by development. Thus, an etching mask pattern 20a having an opening 20b is formed. At a position of the opening 20b, the second-color color filter or the third-color color filter is formed at a later step.

The photosensitive resin material may be, for example, an acrylic resin, an epoxy-based resin, a polyimide-based resin, a phenol novolak-based resin, or other photosensitive resins may be used alone, or a mixture or copolymer of two or more of these resins. Examples of an exposure machine used in a photolithography process of patterning the photosensitive resin layer include a scanner, a stepper, an aligner, and a mirror projection aligner. The exposure may also be performed by direct drawing with an electron beam, drawing with a laser, or the like. In particular, a stepper or a scanner is generally used to form the first-color color filter 14 of a solid-state imaging device that needs to be miniaturized.

For fabrication of patterns with high resolution and high precision, the photosensitive resin material is preferably a generally used photoresist. Use of a photoresist enables formation of patterns, whose shape is easily controllable, with high dimensional accuracy, compared with a case where the patterns are formed of a photosensitive color filter material.

The photoresist used in this case preferably has high dry etching resistance. When the photoresist is used as an etching mask material for use in dry etching, development of the photoresist is very often followed by thermosetting, called post baking, to improve a selection ratio, which is an etching rate of the etching mask material to a material to be etched. If the process includes thermosetting, however, it may be difficult to remove the residual resist used as the etching mask, after dry etching. Accordingly, the photoresist preferably has a good selection ratio to the material to be etched even when thermosetting is not used. When the photoresist does not have a good selection ratio, the photoresist material needs to have a large thickness, but the photoresist material having a large thickness makes it difficult to form a fine pattern. Thus, the photoresist is preferably a material having high dry etching resistance.

Specifically, an etching rate ratio (selection ratio) of the photosensitive resin material which is the etching mask and the first-color color filter material which is to be dry etched is preferably 0.5 or more, and more preferably 0.8 or more. With this selection ratio, the first-color color filter 14 can be etched while not all the etching mask pattern 20a is eliminated. When the first-color color filter material has a thickness of approximately 0.2 μm or more and 0.7 μm or less, the photosensitive resin layer desirably has a thickness of approximately 0.5 μm or more and 2.0 μm or less.

Furthermore, the photoresist used may be a positive resist or a negative resist. However, considering removal of the photoresist after etching, a positive resist, which becomes more soluble by external factors as the chemical reaction proceeds, is more preferable than a negative resist, which becomes more curable as the chemical reaction proceeds.

Thus, the etching mask pattern is formed.

As shown in FIG. 4(a), a part of the color filter curing layer exposed from the opening 20b is removed by dry etching using the etching mask pattern and a dry etching gas.

Examples of a dry etching method include use of ECR, parallel plate magnetron, DRM ICP, and dual-frequency RIE (reactive ion etching). The etching method is not particularly limited, but may preferably be a method enabling control, with an etching rate or an etched shape remaining unchanged, even for patterns with different line widths or areas, such as large-area patterns each having a width of several millimeters or more, or minute patterns each having a width of several hundred nanometers. A dry etching method to be used may preferably have a control mechanism enabling planarity in dry etching across a surface of a wafer with a size of approximately 100 mm to 450 mm.

The dry etching gas may be a gas having reactivity (oxidization, reduction), or a gas having etching properties. Examples of the gas having reactivity include a gas containing fluorine, oxygen, bromine, sulfur, chlorine or the like. Furthermore, noble gases containing an element, such as argon or helium, having low reactivity and enabling etching by physical impact of ions, can be used singly or in a mixture. When performing dry etching under a plasma environment using a gas, the gas is not necessarily limited to gases mentioned above, as long as the gas causes a reaction forming a desired pattern. In the present embodiment, a gas in which 90% or more of a total gas flow is a noble gas or the like that performs etching mainly by physical impact of ions is used at an early stage, and then an etching gas in which a fluorine gas or an oxygen gas is mixed is used to improve an etching rate by using a chemical reaction as well.

In the present embodiment, the semiconductor substrate 10 is composed of a material principally made of silicon. Therefore, the dry etching gas for etching the transparent resin layer is desirably a gas that etches the transparent resin layer and does not easily etch the underlying semiconductor substrate 10. When a gas that etches the semiconductor substrate 10 is used, multistage etching may be performed in which a gas that etches the semiconductor substrate 10 is first used, and then the gas is switched to another gas that does not easily etch the semiconductor substrate 10. The type of the etching gas is not limited, as long as the etching gas does not influence the semiconductor substrate 10, enables the color filter material to be etched to have a shape close to a vertical shape by using the etching mask pattern 20a, and leaves no residue of the color filter material.

Specifically, a single gas of a noble gas, or a mixed gas containing a reactive gas and a noble gas, in which 90% or more of a total gas flow is a noble gas, is used to etch the color filter curing layer and a part of the transparent resin layer 12. Here, in order to reduce damage to the semiconductor substrate 10, etching may be stopped halfway to switch a gas to one that does not easily etch the semiconductor substrate 10.

In the next stage, a part or the entirety of the transparent resin layer 12 is etched by using an oxygen-based gas that does not easily etch the semiconductor substrate 10. FIG. 4 illustrates a configuration in which a part of the transparent resin layer 12 in the thickness direction is etched. However, the entire thickness in the thickness direction may also be etched. A configuration in which a part of the transparent resin layer 12 in the thickness direction is etched is shown in FIGS. 1(a) and 1(b), whereas a configuration in which the entirety of the transparent resin layer 12 in the thickness direction is etched is shown in FIGS. 1(c) and 1(d).

Thus, the first-color color filter 14 is formed.

### (Step of Forming Partition Wall (Second Step))

Further, as shown in FIG. 4(a), a by-product generated in dry etching of the color filter curing layer and the transparent resin layer 12 is provided as the partition walls 17 disposed between the first, second, and third-color color filters 14, 15, and 16. The partition walls 17 are formed from a by-product generated by the reaction of the first-color color filter material and the transparent resin layer material with the dry etching gas. When anisotropic etching is performed, it is important to control side wall protective layers that will be formed by adhesion of the by-product of dry etching to the side walls. The way and amount of adhesion of the by-products vary depending on the dry etching conditions.

In the method of producing a solid-state imaging device of the present embodiment, the color filter curing layer is etched, and then the openings formed by the etching are filled with the second and third-color color filter materials to thereby form color filters of multiple colors. Accordingly, in dry etching, it is necessary to first etch the color filter curing layer vertically, and control the pattern size. Therefore, the way and amount of adhesion of the by-product to the side wall in dry etching are required to be controlled.

When a fluorine-based gas is used for dry etching in the production method of the present embodiment, the silicon mainly used in the underlying semiconductor substrate 10 may be unavoidably etched by chemical reaction. Therefore, it is necessary to adjust the gas flow rate of a fluorine-based gas so as not to be increased more than necessary. The fluorine-based gas to be used may be appropriately selected from, for example, the group of gases consisting of carbon and fluorine, such as CF₄, C₂F₆, C₃F₈, C₂F₄ and C₄F₈. Further, two or more of the fluorine-based gases may be mixed for use as a dry etching gas.

On the other hand, a reaction using physical impact of ions can increase the amount of deposition (adhesion) of the by-product to the side wall. For example, a dry etching gas used may be a noble gas, such as helium (He), neon (Ne), argon (Ar), krypton (Kr), or xenon (Xe), and particularly Ar or He is preferred.

The present embodiment uses a dry etching gas, in which 90% or more of the total gas flow is a noble gas including less reactive elements such as Ar or He, mixed with one or more reactive gases such as fluorine-based gas and an oxygen-based gas. Accordingly, it is possible to improve the etching rate by using chemical reaction, and control the amount of the by-product adhering to the side walls. Thus, the by-product adhering to the side walls of the first-color color filters 14 are formed as the partition walls 17.

Under the above dry etching conditions, the color filter curing layer and a part of the transparent resin layer 12 are dry etched. Then, a single gas of O₂ or noble gas, or a mixed gas of these gases is used to dry etch a part or the entirety of the transparent resin layer 12 to thereby remove the color filter curing layer at desired positions on the entire surface of the semiconductor substrate 10 while reducing the influence of in-plane variation in etching of the semiconductor substrate 10.

By the above dry etching, the first-color color filter 14 having the partition wall 17 made of the by-product generated by dry etching is obtained without generating a residue of color filter material. Since the partition wall 17 prevents leakage of light and dye transfer from another color, a color mixture prevention effect is achieved.

Then, the remaining etching mask pattern 20a is removed (see FIG. 4(b)). For example, the etching mask pattern 20a may be removed by a removal method of dissolving and peeling off the etching mask pattern 20a by using a chemical solution or a solvent without influencing the first-color color filter 14. Examples of the solvent for removing the etching mask pattern 20a include an organic solvent such as N-methyl-2-pyrrolidone, cyclohexanone, diethylene glycol monomethyl ether acetate, methyl lactate, butyl lactate, dimethyl sulfoxide, diethylene glycol diethyl ether, propylene glycol monomethyl ether, propylene glycol monoethyl ether, or propylene glycol monoethyl ether acetate, which may be used alone, or in a mixture of two or more. The solvent used is preferably a solvent that does not affect the color filter material. As long as the color filter material is not affected, a separation method using an acidic chemical agent may also be used.

A removal method other than the wet process using a solvent or the like may also be employed. The etching mask pattern 20a can be removed by a method using an ashing technique which is a resist ashing technique using photoexcitation or oxygen plasma. These methods may also be used in combination. For example, a layer altered by dry etching of an outer layer of the etching mask pattern 20a is first removed by the ashing technique, which is the ashing technique using photoexcitation or oxygen plasma, followed by removal of the remaining layer by wet etching using a solvent or the like. The etching mask 20 may also be removed only by ashing as long as the first-color color filter material is not damaged. Furthermore, not only a dry process such as ashing but also a polishing step by CMP or the like may be used.

Through the above steps, the patterning of the first-color color filters 14 and the partition walls 17 are completed.

### (Step of Forming Patterns of Second-Color and Subsequent Color Filters (Third Step))

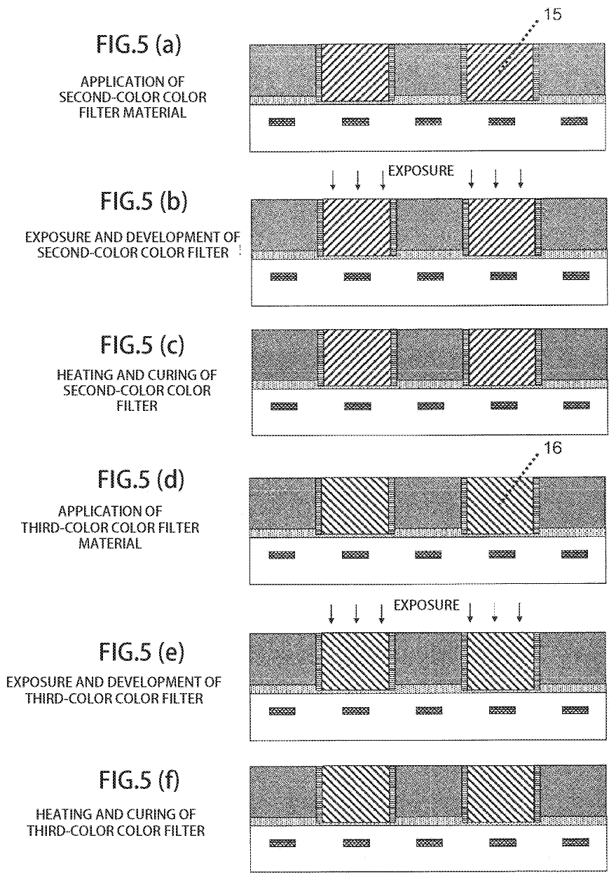

Next, as shown in FIGS. 5(a) to 5(f), the second and third-color color filters 15 and 16 having a color different from that of the first-color color filter 14 are formed. The pattern of the second and third-color color filters 15 and 16 are formed, while using the first-color color filter 14 and the partition wall 17 as a guide pattern, by using a photosensitive color filter material containing a photo-curable resin, and selectively exposing the photosensitive color filter material by the conventional method.

First, as shown in FIG. 5(a), a photosensitive color filter material is applied as the second-color color filter material to the entire surface of the semiconductor substrate 10 on which the first-color color filter 14 and the partition wall 17 are patterned, followed by drying to form a second-color color filter layer 15. The photosensitive color filter material used includes a negative photosensitive component that is curable by exposure to light.

Specifically, a thickness C1 [nm] of the second-color color filter 15 is set so that the following formulas (1), (2), and (3a) are satisfied:

200 [nm]≤A≤700 [nm] (1)

0 [nm]<B≤200 [nm] (2)

A+B−200 [nm]≤C1≤A+B+200 [nm] (3a)

where A [nm] represents the thickness of the first-color color filter 14, B [nm] represents the thickness of the transparent resin layer 12, and C1 [nm] represents the thickness of the second-color color filter 15.

FIGS. 5(a) to 5(f) illustrate a case of A+B=C1, but the only requirement is that the thickness C1 is within the range of (A+B)±200 [nm] as shown in formula (3a).

As long as the second-color color filter 15 has the thickness C1 within the above range, a color filter containing a thermosetting resin and a photo-curable resin sufficient for curing and having a pigment concentration at which desired spectral characteristics can be obtained.

Next, as shown in FIG. 5(b), a portion where the second-color color filter 15 is to be formed is exposed by using a photomask to selectively photo-cure the patterning area of the second-color color filter 15 so that the color filter material of the second color in the area other than the patterning area that is not selectively exposed in the development step (a portion where the third-color color filter is to be formed) is removed. Next, as shown in FIG. 5(c), the second-color color filter material is cured by performing curing by high temperature heating in order to improve adhesion between the patterning area of the second-color color filter layer 15 and the semiconductor substrate 10 after exposure and development and to improve heat resistance in actual use of the device. Thus, the pattern of the second-color color filter 15 is formed. The temperature used for curing is preferably 200° C. or more.

Next, as shown in FIG. 5(d), a third-color color filter material is applied and dried on the entire surface of the semiconductor substrate 10. That is, a third-color color filter material layer is formed by applying the third-color color filter material to the entire surface of the second-color color filter material in the area other than the patterning area of the second-color color filter 15. Next, as shown in FIG. 5(e), a portion where the third-color color filter 16 is to be formed in the third-color color filter material layer is selectively exposed for photo-curing so that the third-color color filter material in the area other than the patterning area of the third-color color filter 16 that is not exposed in the development step is removed.

Next, as shown in FIG. 5(f), the third-color color filter material is cured by high temperature heating in order to improve adhesion between a portion of the third-color color filter layer 16 and the semiconductor substrate 10 after the exposure and development and to improve heat resistance in actual use of the device. Thus, the third-color color filter 16 is formed.

Color filters of a desired number of colors can be formed by repeating a similar step of forming patterns after the second-color color filter 15.

Specifically, a thickness C2 [nm] of the third-color color filter 16 is set so that the following formulas (1), (2), and (3b) are satisfied:

200 [nm]≤A≤700 [nm] (1)

0 [nm]<B≤200 [nm] (2)

A+B−200 [nm]≤C2≤A+B+200 [nm] (3b)

where C2 [nm] represents the thickness of the third-color color filter 16.

FIGS. 5(a) to 5(f) illustrate a case of A+B=C2, but the only requirement is that the thickness C2 is within the range of (A+B)±200 [nm] as shown in the formula (3b).

As long as the third-color color filter 16 has the thickness C2 within the above range, a color filter containing a thermosetting resin and a photo-curable resin sufficient for curing and having a pigment concentration at which desired spectral characteristics can be obtained.

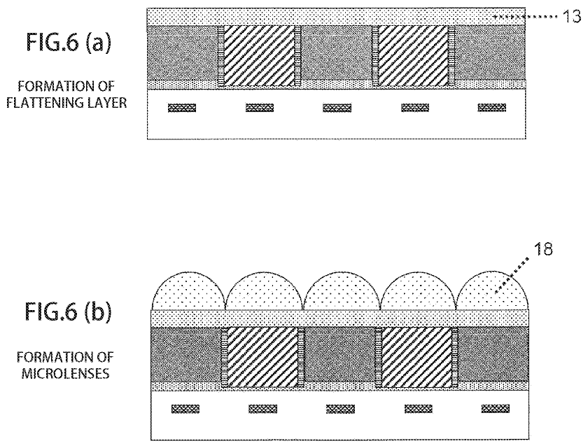

Then, as shown in FIG. 6(a), the flattening layer 13 is formed on the formed color filters 14, 15, and 16 and the partition wall 17. The flattening layer 13 can be formed by using, for example, a resin containing one or more of the resin materials such as an acrylic resin. The flattening layer 13 can be formed by applying and heat-curing the resin material on the color filters 14, 15, and 16 of a plurality of colors and the partition walls 17. Alternatively, the flattening layer 13 may also be formed by using, for example, a compound such as an oxide or a nitride. In this case, the flattening layer 13 can be formed by various film forming methods such as vapor deposition, sputtering, and CVD.

The flattening layer 13 has a thickness of, for example, 1 [nm] or more and 300 [nm] or less. Preferably, the flattening layer 13 has a thickness of 100 [nm] or less, and more preferably of 60 [nm] or less.

Finally, as shown in FIG. 6(b), microlenses 18 are formed on the flattening layer 13. The microlenses 18 are formed by a known technique such as a fabrication method using a thermal flow, a microlens fabrication method using a gray tone mask, or a microlens transfer method to the flattening layer 13 using dry etching.

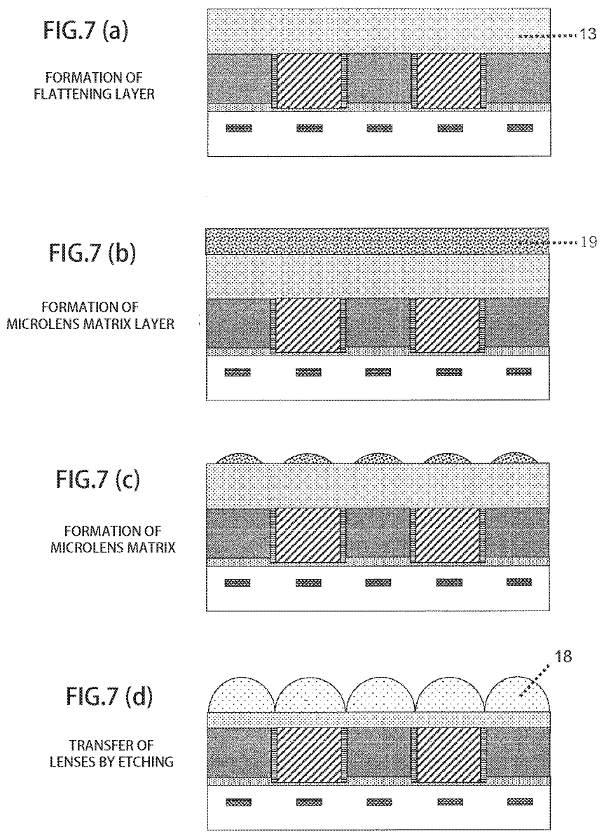

In a method of forming microlenses 18 by using a dry etching patterning technique, as shown in FIG. 7(a), the flattening layer 13 which finally provides microlenses 18 is first formed on the color filters 14, 15, and 16 of a plurality of colors and the partition walls 17.

Next, as shown in FIG. 7(b), a microlens matrix layer 18 for forming a matrix of microlenses 18 is applied and formed on the flattening layer 13. The materials for the microlens matrix layer 19 is a resin including one or more resin materials such as acrylic resin.

Next, as shown in FIG. 7(c), a matrix of microlenses 18 is formed by exposure using a photomask (not shown) by a thermal flow method.

Next, as shown in FIG. 7(d), the lens matrix shape is transferred to the flattening layer 13 by a dry etching technique while using the lens matrix as a mask. By selecting a height and a material of the lens matrix and adjusting conditions of dry etching, a suitable lens shape can be transferred to the flattening layer 13.

With the above method, the microlenses 18 can be formed with good controllability. It is desired to fabricate the microlenses 18 with the thickness, which is a height from a lens top to a lens bottom, in the range from 300 to 800 nm by using the above method.

### (Color Filters of Four or More Colors)

In formation of color filters of four or more colors, a fourth-color and subsequent color filters can be formed by repeating a step similar to that of the second-color color filter 15, after the step of forming the third-color color filter 16. Further, the color filter of the last color is formed by a step similar to that of the third-color color filter 16. Accordingly, the color filters of four or more colors can be produced.

Through the processes described above, a solid-state imaging device of the present embodiment is obtained.

In the present embodiment, the first-color color filter 14 is preferably the color filter that occupies a largest area. Then, the second and third-color color filters 15 and 16 are each formed by photolithography using a photosensitive color resist.

The technique of using a photosensitive color resist is a conventional technique of producing color filter patterns. Since the first-color color filter material is applied to the entire surface of the transparent resin layer 12 and then heated at a high temperature, the semiconductor substrate 10 can be very strongly adhered to the transparent resin layer 12. Accordingly, by using the pattern of the first-color color filter 14 and the partition wall 17 with good adhesion and good rectangularity as the guide pattern, the second and third-color color filters 15 and 16 can be formed so as to fill areas whose four sides are surrounded. Thus, even when photosensitive color resists are used for the second-color and subsequent color filters, resolution of the color resists does not need to be emphasized as in the conventional art. Accordingly, the amount of the photo-curable component in the photo-curable resin can be decreased, and thus a ratio of the pigment in the color filter material can be increased. This contributes to thinning of the color filters 15 and 16.

In the present embodiment, both the thermosetting resin and the photo-curable resin are used for the first-color color filter 14. The first-color color filter 14 is desirably formed of a color filter material in which a content percentage of a resin component and the like involved in photo-curing is low and a content percentage of a pigment is high. In particular, the content percentage of the pigment in the first-color color filter material is desirably 70% by mass or more. Thus, even when the first-color color filter material contains pigment at a concentration at which curing is insufficient in a conventional photolithography process using a photosensitive color resist, the first-color color filter 14 can be formed with good precision and with no residue or peeling.

In the present embodiment, since the partition wall 17, formed between the first-color color filter 14 and the second and third-color color filters 15 and 16, prevents leakage of light and dye transfer from another color, a color mixture can be reduced.

As described above, according to the present embodiment, all the color filters can be reduced in thickness, and thus a total distance from the top of the microlens to the device can be decreased, and color mixture can be reduced by providing the partition walls between the color filters of plurality of colors. This makes it possible to provide a high-definition solid-state imaging device in which less color mixture occurs and all color filters arranged in pattern have high sensitivity.

### Second Embodiment

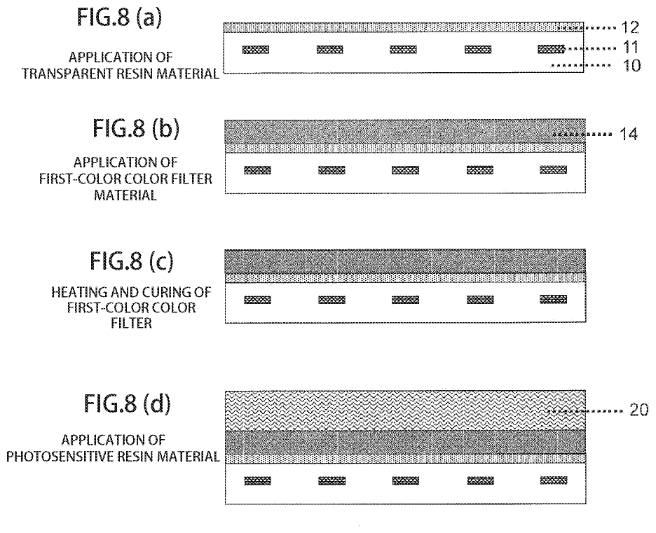

With reference to FIGS. 8(a) to 8(d), a solid-state imaging device and a method of manufacturing the solid-state imaging device according to a second embodiment of the present invention will be described below. The solid-state imaging device according to the second embodiment of the present invention has a structure similar to that of the first embodiment.

The second embodiment differs from the first embodiment in a step in curing of the first-color color filter 14. Therefore, a step of curing the first-color color filter 14 will be described below.

### <Configuration of Solid-State Imaging Device>

The solid-state imaging device according to the present embodiment is characterized in that the first-color color filter material does not contain photosensitive resin material and contains only a thermosetting resin as curable component. Since it contains only the thermosetting resin, there is an advantage that the pigment concentration can be higher and thus the first-color color filter has smaller thickness. As shown in FIGS. 1(a) to 1(d), a solid-state imaging device according to the present embodiment includes a semiconductor substrate 10 including a plurality of photoelectric conversion elements 11 that are two-dimensionally arranged, a microlens group composed of a plurality of microlenses 18 that are arranged above the semiconductor substrate 10, and a color filter layer and the partition wall 17 provided between the semiconductor substrate 10 and the microlenses 18. The color filter layer is composed of color filters 14, 15, and 16 of a plurality of colors that are arranged in a predetermined regular pattern. The partition wall 17 are each disposed between the color filters 14, 15, and 16 of the plurality of colors.

FIGS. 1(a) and 1(b) illustrate a configuration in which a transparent resin layer 12 provided under second and third-color color filters is thinner than a transparent resin layer 12 provided under first-color color filter layer. FIGS. 1(c) and 1(d) illustrate a configuration in which a transparent resin layer 12 is provided under first-color color filter layer but is not provided under the second and third-color color filters.

Furthermore, a flattening layer 13 is provided between the color filter layer and the microlens group composed of the plurality of microlenses 18.

In the solid-state imaging device according to the second embodiment, components having configurations similar to those of the solid-state imaging device according to the first embodiment are given reference numerals which are the same as the reference numerals used in the first embodiment. Specifically, the semiconductor substrate 10 having the photoelectric conversion elements 11, as well as the transparent resin layer 12, the color filters 14, 15, and 16, the partition wall 17, the flattening layer 13, and the microlenses 18 all have respective configurations similar to those of the solid-state imaging device of the first embodiment. Thus, a detailed description of components in common with the components of the solid-state imaging device according to the first embodiment is omitted. The same applies to other embodiments.

### <Method of Manufacturing Solid-State Imaging Device>

Next, with reference to FIGS. 8(a) to 8(d), the method of manufacturing the solid-state imaging device of the present embodiment will be described.

As shown in FIG. 8(a), a transparent resin material is applied and heated on a semiconductor substrate 10 that includes a plurality of two-dimensionally arranged photoelectric conversion elements 11 to thereby form a transparent resin layer 12. The transparent resin layer 12 has an effect of flattening the surface of the semiconductor substrate 10 and improving the adhesion to the color filter material.

Next, as shown in FIGS. 8(b) to 8(d), a first-color color filter material layer 14 is formed, and then a photosensitive resin material layer is formed thereon. The first-color color filter material layer 14 of the present embodiment contains a thermosetting resin but no photo-curable resin. Further, when the content percentage of the pigment is increased, solvent resistance may be reduced. For this reason, a thermosetting resin having solvent resistance is used and heated at a high temperature to perform heat curing with high crosslinking density. Specifically, a high temperature curing step is performed at 170° C. or more, and more desirably at 250° C. or more. On the first-color color filter 14 formed at this high temperature curing step, a photosensitive resin material is applied and dried to form an etching mask 20.

Then, an etching mask pattern having openings is formed by performing exposure and development using a photomask so that portions where the second and third-color color filters 15 and 16 are to be formed are opened. These steps are similar to those of the first embodiment mentioned above.

According to the present embodiment, since the first-color color filter 14 contains only the thermosetting component but no photosensitive component, the present embodiment has an advantage that a high pigment concentration is more likely to be easily achieved. Furthermore, by setting the thermosetting temperature to a high temperature, the first-color color filter 14 can have higher solvent resistance.

The second embodiment further has the following advantageous effects in addition to those described in the first embodiment. Since the first-color color filter 14 is formed of a thermosetting resin which is a thermosetting component, it is possible to easily achieve a high concentration of the pigment component and form the first-color color filter 14 having a small thickness and desired spectral characteristics.

### Third Embodiment

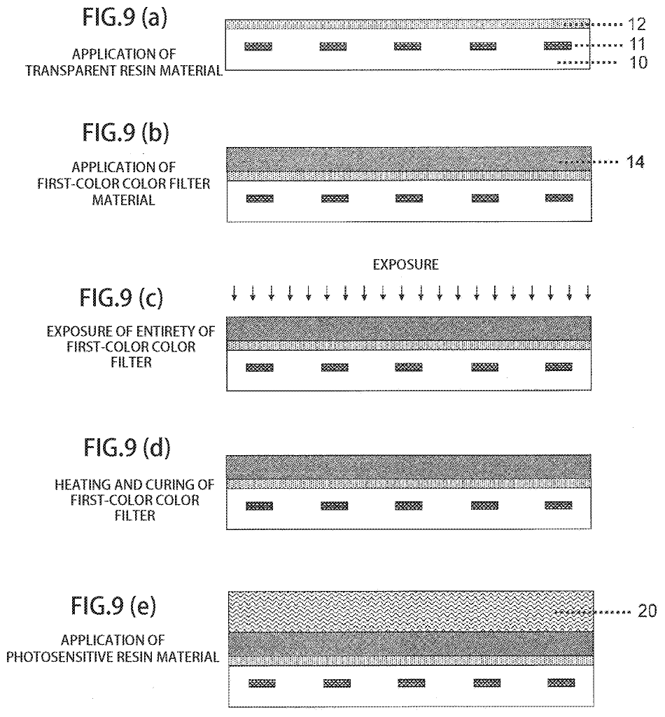

With reference to FIGS. 9(a) to 9(e), a solid-state imaging device and a method of manufacturing the solid-state imaging device according to a third embodiment of the present invention will be described below.

### <Configuration of Solid-State Imaging Device>

The solid-state imaging device according to the present embodiment is characterized in that the first-color color filter material contains only a photosensitive resin as a curable component. In the present embodiment, in which the photosensitive resin is used, conventional lithography patterning is not performed. Instead, photo-curing by entire surface exposure is performed, followed by heat-curing to evaporate water from the color filter by high temperature heating. Accordingly, compared with the conventional method, the present embodiment can reduce the amount of photosensitive curable component and increase the pigment concentration. Thus, the present embodiment has an advantage that the first-color color filter 14 is more likely to have a small thickness.

A structure of the solid-state imaging device according to the present embodiment is similar to those of the first and second embodiments. However, the present embodiment differs from the first and second embodiments in a step in curing of the first-color color filter 14. Therefore, a curing step and a patterning step for the first-color color filter 14 will be described below.

### <Method of Manufacturing Solid-State Imaging Device>

Next, with reference to FIGS. 9(a) to 9(e), the method of manufacturing the solid-state imaging device of the present embodiment will be described.

As shown in FIG. 9(a), a transparent resin material is applied and heated on a semiconductor substrate 10 to form a transparent resin layer 12.

Next, as shown in FIG. 9(b), the first-color color filter material layer 14 is formed by application on the transparent resin layer 12.

Next, as shown in FIG. 9(c), the entire surface of the first-color color filter material layer 14 is exposed for photo-curing.

At this time, when the first-color color filter material layer 14 contains a sufficient amount of photosensitive component for curing of the first-color color filter layer 14 and has sufficient solvent resistance, a photosensitive resin mask material 20 shown in FIG. 9(e) is formed. After the photosensitive resin mask material 20 is patterned, portions where the second-color and subsequent color filters are to be formed are formed by dry etching, followed by high temperature heating at 170° C. or more to thereby perform heat-curing of the first-color color filter 14.

When no high temperature heating step is performed to the first-color color filter material layer prior to dry etching, etching can be easily performed at the dry etching step compared to the case where the high temperature heating step is performed, since the first-color color filter material layer 14 has a soft structure. This is effective in reducing a residue or the like.

On the other hand, when the first-color color filter material layer 14 contains a photosensitive component insufficient for exhibition of good solvent resistance, as shown in FIG. 9(d), it is desirable to perform a high temperature heating step at 170° C. or more to sufficiently cure the first-color color filter material layer 14.

The steps subsequent to the above steps are similar to those described in the above first embodiment.

According to the present embodiment, since the color filter material layer is heated by using photo-curing by entire surface exposure and heat-curing by heating, the amount of photosensitive component can be reduced compared with the color filter material formed by conventional technique, and the content percentage of pigment in the color filter can be easily increased. This is advantageous in that the same spectral characteristics as those of the conventional photosensitive resist can be achieved due to the increased pigment concentration, even when the color filter material layer has a smaller thickness. Furthermore, by setting the thermosetting temperature to a high temperature, the first-color color filter 14 can have higher solvent resistance.

### EXAMPLES

The solid-state imaging device according to an embodiment of the present invention and the solid-state imaging device according to the conventional method will be specifically described below.

### Example 1

A coating liquid containing a silicon-based resin was spin coated at a rotational speed of 2000 rpm on a semiconductor substrate including photoelectric conversion elements two-dimensionally arranged, and heated at 200° C. for 20 minutes by using a hot plate to cure the resin. Thus, a transparent resin layer was formed on the semiconductor substrate. The transparent resin layer had a thickness of 100 nm, and a transmittance to visible light of 91%.

Next, a green pigment dispersion containing a photosensitive resin and a thermosetting resin was spin coated at a rotational speed of 1000 rpm as a first-color color filter material containing a green pigment as a first color. The green pigment of the first-color color filter material was C.I. PG 58 in the Color Index. A concentration of the green pigment in the first-color color filter material was 70% by mass, and a thickness of the first-color color filter material was 500 nm.

Then, for curing of the green filter material, the entire surface was exposed by using a stepper, which is an i-line exposure device, to cure the photosensitive component. By curing the photosensitive component, the surface of the green filter was cured. Subsequently, the resultant object was baked at 230° C. for 6 minutes to thermally cure the green filter.

Then, the resultant object was spin coated with a positive resist (OFPR-800: manufactured by Tokyo Ohka Kogyo Co., Ltd.) at a rotation speed of 1,000 rpm by using a spin coater, followed by prebaking at 90° C. for 1 minute. Thus, a sample was fabricated in which a positive photoresist was applied with a thickness of 1.5 μm as an etching mask.

The sample was exposed via a photomask by photolithography. The exposure was performed by using an exposure device having a light source of an i-line wavelength. When irradiated with ultraviolet light, the positive resist causes a chemical reaction and becomes soluble in a developing solution.

Then, a development step was performed by using, as a developing solution, 2.38% by mass of TMAH (tetramethylammonium hydride) to form an etching mask having openings at positions where second and third-color color filters are to be formed. When a positive resist is used, development is very often followed by dehydration baking to cure the positive resist. This time, however, in order to facilitate removal of the etching mask after dry etching, no bake step was performed. Accordingly, the resist was not cured and a selection ratio was not expected to be increased. Thus, the resist was formed to have a thickness of 1.5 μm, which was more than twice the thickness of the first-color color filter which was the green filter. Pattern openings in this case were each 1.1 μm×1.1 μm. Thus, an etching mask pattern using a positive resist was formed.

Then, dry etching of the green filter layer was performed by using the formed etching mask pattern. At this time, an ICP type dry etching apparatus was used. The sample was dry etched stepwise with the dry etching conditions being changed so as not to affect the underlying semiconductor substrate.

First, by using a mixture of three gases, i.e., CF₄ gas, O₂ gas and Ar gas, etching was performed. A flow rate of each of the CF₄ gas and the O₂ gas was set to 5 mL/min, and a flow rate of the Ar gas was set to 200 mL/min. Specifically, the Ar gas flow rate in a total gas flow rate was 95.2%. Further, the dry etching conditions at this time were set such that the pressure in the chamber was 1 Pa, and the RF power was 500 W, and the coil power was 1000 W. At the stage where the green filter layer was dry etched by using these conditions, the dry etching conditions were changed as follows.

Next, an O₂ gas alone was used, and the etching conditions were set such that an O₂ gas flow rate was 300 mL/min, a chamber internal pressure was 2 Pa, a RF power was 0 W, and a coil power was 1000 W. Under these conditions, dry etching of the transparent resin layer was performed. By performing dry etching under these conditions, the surface layer of the etching mask that has been damaged and altered by dry etching was removed, and the residue of the green filter and the transparent resin layer were etched by 50 nm.

Further, during the above dry etching, a partition wall containing a by-product of the green filter material and the transparent resin material, and a dry etching gas was formed on the side wall of the green filter pattern. The dimension (width) of the partition wall can be controlled by adjusting the time of the dry etching condition.

In the above dry etching conditions, approximately 500 nm of the green filter and approximately 50 nm of the transparent resin layer were dry etched. The partition wall formed by using their by-product had a dimension of 35 nm.

Then, the positive resist used as an etching mask was removed. The removal was performed by using a solvent. Specifically, the positive resist was removed by using a spray cleaning device using a stripping solution 104 (manufactured by Tokyo Ohka Kogyo Co., Ltd.).

### (Fabrication of Second-Color Color Filter)

Then, a step of forming a second-color color filter was performed. In order to form the second-color color filter, a photosensitive blue resist containing a blue pigment dispersion was applied to the entire surface of the semiconductor substrate. Here, an HMDS treatment may also be performed prior to the application of the blue resist in order to improve adhesiveness.

Then, the blue resist was selectively exposed by photolithography and developed to form a blue filter pattern. Pigments used for the blue resist were C.I. PB 156 and C.I. PV 23 in the Color Index, and a pigment concentration was 50% by mass. The blue filter had a thickness of 550 nm. Further, a photosensitive acrylic resin was used as a resin which is a main component of the blue resist.

Then, in order to strongly cure the blue filter layer, curing was performed in an oven at 200° C. for 30 minutes. Once the second-color color filter was subjected to this heating step, no peeling, pattern deformation, or the like was found even when the second-color color filter was subjected to steps such as a step of forming a third-color color filter. The blue filters were formed with good rectangularity because they were each surrounded by the green filters having good rectangularity and the partition walls. Thus, it was found that the blue filters had been cured with good adhesion to the bottoms and the surrounding filters.

### (Fabrication of Third-Color Color Filter)

Then, a step of forming a third-color color filter was performed. In order to form the third-color color filter, a photosensitive red resist containing a red pigment dispersion was applied to the entire surface of the semiconductor substrate.

Then, the red resist was selectively exposed by photolithography and developed to form a red filter pattern. Pigments used for the red resist were C.I. PR 254 and C.I. PY 139 in the Color Index, and a pigment concentration was 60% by mass. The red filter had a thickness of 550 nm.

Then, in order to strongly cure the red filter layer, curing was performed in an oven at 200° C. for 30 minutes. Here, the third-color color filters were formed with good rectangularity because they were each surrounded by the green filters having good rectangularity and the partition walls. Thus, it was found that the blue filters had been cured with good adhesion to the bottoms and the surrounding filters.

Through the above steps, the color filters were formed so that a thickness A (500 nm) of the first-color color filter which was the green filter, a thickness B (100 nm) of the transparent resin layer under the first-color color filter, and a thickness C (550 nm) of the second and third-color color filters which were the blue and red filters were the thicknesses according to an embodiment of the present invention. Further, in the present example, the transparent resin layer having a thickness of 50 nm is formed under the second and third-color color filter layers.

Then, the color filters formed through the above steps were spin coated with a coating liquid containing an acrylic resin at a rotation speed of 1,000 rpm, followed by heating and curing the resin at 200° C. for 30 minutes using a hot plate to form a flattening layer.

Finally, on the flattening layer, microlenses each having a height of 500 nm from the lens top to the lens bottom were formed by a transfer method using etchback, which is the known technique mentioned above. Thus, a solid-state imaging device of Example 1 was obtained.

In the solid-state imaging device obtained as described above, 100 nm of the transparent resin layer was formed under the first-color color filter, and 50 nm of the transparent resin layer was formed under the second and third-color color filters. Since the first-color color filter, which is the green filter, uses a thermosetting resin and a small amount of photosensitive resin, the pigment concentration in the green filter can be improved compared with the conventional photosensitive resist. Accordingly, due to improvement in pigment concentration, the same spectral characteristics as a conventional photosensitive resist can be achieved even when the green filter is formed thin. Further, although the second and third-color color filters, which are the blue filter and the red filter, use a photosensitive resin, good sensitivity is achieved since the transparent resin layer is etched by 50 nm, which causes a decrease in distance from the microlens to the semiconductor substrate.

Further, the transparent resin layer has a transmittance to visible light of 91%, and the formed partition wall has a dimension of 35 nm, which satisfied the values in an embodiment of the present invention.

Furthermore, the inside of the color filter material of the first-color color filter which was the green filter was cured by thermosetting, and further the surface of the color filter material of the first-color color filter was cured by exposure using the small amount of photosensitive resin. Accordingly, the color filter material of the first-color color filter had improved solvent resistance. When a green filter material having a high content percentage of pigment is used, the green filter material may react with a solvent or other color filter materials, and this may change spectral characteristics of the green filter material. Thus, combination of thermosetting with photo-curing as described above can improve solvent resistance and reduce or prevent change of spectral characteristics.

### Example 2

Example 2 is an example corresponding to the solid-state imaging device having the configuration described in the second embodiment. As a first-color color filter material of a solid-state imaging device of Example 2, no photo-curable resin was used and only a thermosetting resin was used. The use of only the thermosetting resin can achieve a high pigment concentration and formation of a color filter having a small thickness.

### (Formation of Transparent Resin Layer)

A coating liquid containing a silicon-based resin was spin coated at a rotational speed of 2000 rpm on a semiconductor substrate, and was heat treated at 200° C. for 20 minutes by using a hot plate to cure the resin. Thus, a transparent resin layer was formed. The transparent resin layer had a thickness of 100 nm, and a transmittance to visible light of 91%.

### (Formation of First-Color Color Filter)

A green pigment dispersion containing a thermosetting resin but no photosensitive resin was prepared as the color filter material of the first-color color filter (green filter). The green pigment dispersion was spin coated at a rotational speed of 1000 rpm on a surface of the transparent resin layer. A thermosetting acrylic resin was used as a resin which was a main component of the green pigment dispersion. As a green pigment contained in the green pigment dispersion, C.I. PG 58 in the Color Index was used, and the concentration of the green pigment in the green pigment dispersion was 70% by mass. The green color filter material was applied with a thickness of 500 nm.

Then, the green color filter was baked at 250° C. for 6 minutes to cure the green filter material, and thus a green filter layer was formed. By baking the green color filter at a high temperature of 250° C., a crosslinking density of the thermosetting resin was increased, and thus the green pigment was more strongly cured.

An etching mask was formed by the method described in Example 1, and part of the green filter layer and the transparent resin layer was etched. Then, the positive resist used as an etching mask was removed by the method described in Example 1.

### (Fabrication of Second and Third-Color Color Filters and the Like)

In Example 2, thereafter, the second and third-color color filters, a flattening layer, and microlenses were formed by a method similar to that of Example 1. Thus, the solid-state imaging device of Example 2 was formed.

Through the above steps, in Example 2 as in Example 1, a thickness A (500 nm) of the green filter which was the first-color color filter, a thickness B (100 nm) of the transparent resin layer under the green filter, and a thickness C (550 nm) of the blue and red filters which were the second and third-color color filters, a visible light transmittance D (91%), and a partition wall dimension E (35 nm) satisfied the values in an embodiment of the present invention. Further, in the present example, the transparent resin layer having a thickness of 50 nm is formed under the second and third-color color filter layers.

### Example 3

Example 3 is an example corresponding to the solid-state imaging device having the configuration described in the third embodiment. As a first-color color filter material of a solid-state imaging device of Example 3, no thermosetting resin was used and only a photo-curable resin was used. However, unlike a conventional step as described later at which a photosensitive color resist is patterned, the first-color color filter material was cured by entire surface exposure. This can achieve a high content percentage of pigment and formation of a color filter having a small thickness.

### (Formation of Transparent Resin Layer)

A coating liquid containing an acrylic resin was spin coated at a rotational speed of 2000 rpm on a semiconductor substrate, and was heat treated at 200° C. for 20 minutes by using a hot plate to cure the resin. Thus, a transparent resin layer was formed. The transparent resin layer had a thickness of 100 nm, and a transmittance to visible light of 91%.

### (Formation of First-Color Color Filter)

A green pigment dispersion containing a photosensitive resin but no thermosetting resin was prepared as the color filter material of the first-color color filter (green filter). The green pigment dispersion was spin coated at a rotational speed of 1000 rpm on a surface of the transparent resin layer. A photo-curable acrylic resin was used as a resin which was a main component of the green pigment dispersion. As a green pigment contained in the green pigment dispersion, C.I. PG 58 in the Color Index was used, and the concentration of the green pigment in the green pigment dispersion was 70% by mass. The green color filter material was applied with a thickness of 500 nm. Then, an entire surface of the wafer was exposed by means of an i-line stepper exposure apparatus to photo-cure the green filter material.

Then, the photo-cured green filter was baked at 230° C. for 6 minutes to cure the green filter material, and thus a green filter layer was formed.

### (Formation of First-Color Color Filter)

An etching mask was formed by the method described in Example 1, and part of the green filter layer and the transparent resin layer was etched. Then, photosensitive resin mask material was removed by the method described in Example 1.

### (Fabrication of Second and Third-Color Color Filters and the Like)

In Example 2, thereafter, the second and third-color color filters, a flattening layer, and microlenses were formed by a method similar to that of Example 1. Thus, the solid-state imaging device of Example 2 was formed.

Through the above steps, in Example 3 as in Example 1, a thickness A (500 nm) of the green filter which was the first-color color filter, a thickness B (100 nm) of the transparent resin layer under the green filter, and a thickness C (550 nm) of the blue and red filters which were the second and third-color color filters, a visible light transmittance D (91%), and a partition wall dimension E (35 nm) satisfied the values in an embodiment of the present invention.

In Example 3, after the green filter which was the first-color color filter was cured by irradiation with ultraviolet light, the green filter was heat-cured by high temperature heating. This is because when the content percentage of the pigment is high, even if the green filter is cured by photo-curing, the green filter may be peeled off at a development step at which the photosensitive resin mask material used as the etching mask is patterned and a cleaning step at which the photosensitive resin mask material is removed after dry etching.

Due to the effect of the present example, the surface of the green pattern was cured with high density using the photosensitive component, and solvent resistance was improved even when the pigment concentration was high.

### <Conventional Method>

Based on the conventional method described in PTL 1, color filters of respective colors were patterned by a photolithography process. However, a thickness of the color filters of three colors, i.e., green, blue, and red, was set to 700 nm, producing thin films, and a transparent resin layer (100 nm) was provided under all the color filters of the respective colors. Except for the above points, a solid-state imaging device according to a conventional method was manufactured in the same manner as Example 1.

### (Evaluations)

In the above examples, although the curing methods of the first-color color filter are different, the thickness A (500 nm) of the green filter which was the first-color color filter, the thickness B (100 nm) of the transparent resin layer under the green filter, and the thickness C (550 nm) of the blue and red filters which were the second and third-color color filters satisfied the thicknesses in an embodiment of the present invention.

For the solid-state imaging devices of these examples, the thicknesses of the three color filters of green, blue, and red are adjusted by conventional photolithography so that they have the same spectral characteristics at 700 nm. Then, the intensities of the red signal, green signal, and blue signal were evaluated.

Table 1 shows an evaluation result of the signal intensities of the respective colors for the solid-state imaging device having a configuration in which the transparent resin layer provided under the second and third-color color filters is thinner than the transparent resin layer provided under the first-color color filter (configuration shown in FIGS. 1(a) and 1(b)).

Further, Table 2 shows an evaluation result of the signal intensities of the respective colors for the solid-state imaging device having a configuration in which no transparent resin layer is provided under the second and third-color color filters (configuration shown in FIGS. 1(c) and 1(d)).

TABLE 1

| | Detected signal intensity ratio | | | |
|---|---|---|---|---|
| | (relative to conventional method) | | | |
| | | Green | Green | |
| | Red | (next to Red) | (next to Blue) | Blue |
| Conventional method | 1.00 | 1.00 | 1.00 | 1.00 |
| Example 1 | 1.12 | 1.10 | 1.10 | 1.11 |
| Example 2 | 1.12 | 1.10 | 1.10 | 1.11 |
| Example 3 | 1.12 | 1.10 | 1.10 | 1.11 |

TABLE 2

| | Detected signal intensity ratio | | | |
|---|---|---|---|---|
| | (relative to conventional method) | | | |
| | | Green | Green | |
| | Red | (next to Red) | (next to Blue) | Blue |
| Conventional method | 1.00 | 1.00 | 1.00 | 1.00 |
| Example 1 | 1.13 | 1.11 | 1.11 | 1.12 |
| Example 2 | 1.13 | 1.11 | 1.11 | 1.12 |
| Example 3 | 1.13 | 1.11 | 1.11 | 1.12 |

As shown in Tables 1 and 2, in the solid-state imaging devices of Examples 1 to 3 in which green filters with a small thickness and good rectangularity are formed by dry etching, and a by-product generated by the dry etching is formed as a partition wall, the intensities of the signals of the respective colors were increased compared with the solid-state imaging device formed by photolithography of conventional art.

This is because, when incident light in an oblique direction of the pixel passes through the color filter and travels toward another color filter pattern, the incident light is blocked by the partition wall, or the light path is changed due to the partition wall. As a consequence, since the light traveling toward another color filter pattern is prevented from entering the other photoelectric conversion element, color mixture is reduced. Further, since dye transfer from another color is also blocked by the partition wall, color mixture is reduced.

As a result of evaluating spectral characteristics after OCF formation by the fabrication method of the present example, no change in the spectral characteristics were observed. This indicates that the green filter having a smaller thickness obtained by the thermosetting and the photo-curing of the present example had sufficient hardness. In order to achieve the color spectral distribution equivalent to that of the green filter having the thickness (700 nm) adjusted by photolithography in the green filter with a smaller thickness, the green filter material having a high content percentage of pigment was used, but no change occurred in the spectral characteristics. The effect of the thickness reduction reduced the distance from the top of the microlens to the device and increased the intensity of the green signal.

Furthermore, the thickness reduction reduced the probability that obliquely incident light passed through a color filter toward another color filter pattern, and the light traveling toward other color filter patterns was prevented from entering other photoelectric conversion elements. Accordingly, color mixture was reduced, and thus the signal intensity was increased.

Furthermore, also when the color filters were formed by the methods of Examples 1 to 3 so that the height of the second-color color filter and the third-color color filter had a value smaller than a value obtained by adding the thickness of the first-color color filter to the thickness of the transparent resin layer, by increasing the content percentage of the pigment while reducing the thickness, the signal intensity was increased as compared with when the color filters were formed by photolithography according to the conventional method.

The present inventors have found that PTLs 2 and 3 do not show a relationship between thicknesses of the color filters and that not all the color filters may have high sensitivity. In addition, the inventors also have found that measures against color mixture are insufficient.

The present invention has an aspect of providing a high-definition solid-state imaging device which has good sensitivity and in which less color mixture occurs.

A solid-state imaging device according to an aspect of the present invention includes: a semiconductor substrate in which a plurality of photoelectric conversion elements are two-dimensionally arranged; a color filter layer which is provided on the semiconductor substrate and in which color filters of a plurality of colors are two-dimensionally arranged corresponding to the respective photoelectric conversion elements in a preset regular pattern; a partition wall provided between the color filters of the plurality of colors; and a transparent resin layer provided between the color filters of a first color selected from the plurality of colors and the semiconductor substrate, wherein the following formulas (1)-(5) are satisfied:

200 [nm]≤A≤700 [nm] (1)

0 [nm]<B≤200 [nm] (2)

A+B−200 [nm]≤C≤A+B+200 [nm] (3)

D≥90[%] (4)

E≤200 [nm] (5)

where A [nm] is a thickness of a color filter of the first color, B [nm] is a thickness of the transparent resin layer, C [nm] is a thickness of a color filter of a color other than the first color, D [%] is a visible light transmittance of the transparent resin layer, and E [nm] is a dimension of the partition wall.

A method for producing a solid-state imaging device according to another aspect of the present invention is a method for producing a solid-state imaging device that includes: a semiconductor substrate in which a plurality of photoelectric conversion elements are two-dimensionally arranged; a color filter layer which is provided on the semiconductor substrate and in which color filters of a plurality of colors are two-dimensionally arranged corresponding to the respective photoelectric conversion elements in a preset regular pattern; a partition wall provided between the color filters of the plurality of colors; and a transparent resin layer provided between the color filters of a first color selected from the plurality of colors and the semiconductor substrate, and the method includes: a first step of forming a color filter of the first color by forming a transparent resin layer on the semiconductor substrate, applying a coating liquid for forming the color filter of the first color, curing the applied coating liquid to form a color filter curing layer on the transparent resin layer, and forming a pattern by removing a first removal target region in the color filter curing layer, which is a region other than an arrangement position of the color filter of the first color, and a second removal target region in the transparent resin layer, which is a region located under the first removal target region in the color filter curing layer, by dry etching; a second step of forming the partition wall from a by-product generated by a reaction of the color filter curing layer and the transparent resin layer, which are removed, by the dry etching in the first step, with a dry etching gas; and a third step of forming a color filter of a color other than the first color by patterning by photolithography, following the second step, in a region other than the arrangement position of the color filter of the first color, where the color filter curing layer and the transparent resin layer have been removed, wherein, in the first step, an entirety of the second removal target region of the transparent resin layer in a thickness direction or a portion thereof, which faces the color filter layer, is removed. According to embodiments of the present invention, a high-definition solid-state imaging device in which less color mixture occurs and all the color filters arranged in a pattern have good sensitivity can be provided.

Although the present invention is described with reference to the above embodiments, the scope of the present invention is not limited to the exemplary embodiments, which are illustrated and described above, and includes all embodiments that achieve the effects equivalent to those according to the present invention. Further, the scope of the present invention is not limited to combinations of features of the invention defined by the claims but should be defined by any desired combination of specific features among all the disclosed features.

### REFERENCE SIGNS LIST

10 . . . Semiconductor substrate
11 . . . Photoelectric conversion element
12 . . . Transparent resin layer
13 . . . Flattening layer
14 . . . First-color color filter
15 . . . Second-color color filter
16 . . . Third-color color filter
17 . . . Partition wall
18 . . . Microlens
19 . . . Microlens matrix layer
20 . . . Etching mask

Obviously, numerous modifications and variations of the present invention are possible in light of the above teachings. It is therefore to be understood that within the scope of the appended claims, the invention may be practiced otherwise than as specifically described herein.

What is claimed is:

1. A solid-state imaging device, comprising:
a semiconductor substrate having a plurality of photoelectric conversion elements formed two-dimensionally therein;
a color filter layer formed on the semiconductor substrate and having a plurality of color filters of multiple colors formed two-dimensionally in a preset regular pattern corresponding to the photoelectric conversion elements;
a partition wall formed between the color filters of the multiple colors; and
a transparent resin layer formed between the semiconductor substrate and a color filter of a first color among the multiple colors,
wherein the color filters, the transparent resin layer, and the partition wall satisfy formulas (1)-(5):
200≤A≤700 (1)
0<B≤200 (2)
A+B−200≤C≤A+B+200 (3)
D≥90 (4)
E≤200 (5)
where A is a thickness, in nm, of the color filter of the first color, B is a thickness, in nm, of the transparent resin layer, C is a thickness, in nm, of a color filter of a color other than the first color, D is a visible light transmittance, in %, of the transparent resin layer, and E is a dimension in a width direction, in nm, of the partition wall.

2. The solid-state imaging device according to claim 1, wherein the transparent resin layer has a refractive index F that satisfies formula (6):
1.40<F<1.65 (6).

3. The solid-state imaging device according to claim 1, wherein the transparent resin layer includes a compound having silicon and oxygen in a main chain.

4. The solid-state imaging device according to claim 1, wherein the partition wall includes at least one selected from the group consisting of zinc, copper, nickel, bromine, chlorine, silicon, and oxygen.

5. The solid-state imaging device according to claim 1, wherein the color filters satisfy formula (7):
A−200≤C≤A+200 (7).

6. The solid-state imaging device according to claim 1, wherein the color filter of the first color comprises a thermosetting resin.

7. The solid-state imaging device according to claim 1, wherein the color filter of the first color comprises a photo-curable resin.

8. The solid-state imaging device according to claim 1, wherein the color filter of the first color comprises a thermosetting resin and a photo-curable resin, and includes the thermosetting resin at a content higher than a content of the photo-curable resin.

9. The solid-state imaging device according to claim 1, wherein the color filter of the first color includes a pigment at a content of 50% by mass or more.

10. The solid-state imaging device according to claim 1, further comprising:
a plurality of microlenses formed on the color filter layer and positioned two-dimensionally corresponding to the photoelectric conversion elements,
wherein each of the microlenses has a height of 300 nm-800 nm from a lens top to a lens bottom thereof.

11. The solid-state imaging device according to claim 1, wherein the color filter of the first color occupies a largest area among the color filters of the multiple colors.

12. The solid-state imaging device according to claim 1, wherein the transparent resin layer is formed between the semiconductor substrate and the color filters of the multiple colors, and
a portion of the transparent resin layer formed under the color filter of the first color has a thickness larger than that of a portion of the transparent resin layer formed under the color filter of the color other than the first color.

13. The solid-state imaging device according to claim 1, wherein no transparent resin layer is formed under the color filter of a color other than the first color.

14. A method for producing a solid-state imaging device, comprising:
forming a transparent resin layer on a semiconductor substrate having a plurality of photoelectric conversion elements being formed two-dimensionally therein;
applying a coating liquid for a color filter of a first color among multiple colors;
curing the coating liquid such that a color filter curing layer is formed on the transparent resin layer;
removing by dry etching a first removal target region in the color filter curing layer, which is a region other than a portion for the color filter of the first color, and a second removal target region in the transparent resin layer, which is a region under the first removal target region in the color filter curing layer, such that a color filter of the first color is formed and patterned on the semiconductor substrate;
forming a partition wall from a by-product of a reaction of a dry etching gas with the color filter curing layer and the transparent resin layer which are removed by the dry etching; and
forming a color filter of a color other than the first color by photolithography at a position where the color filter curing layer and the transparent resin layer have been removed such that color filters of the multiple colors are formed, with the partition wall formed therebetween, in a preset regular pattern corresponding to the photoelectric conversion elements,
wherein the removing of the second removal target region removes either an entirety of the second removal target region or a portion of the second removal target region which faces the color filter layer, in a thickness direction of the second removal target region.

15. The method according to claim 14, wherein the curing of the coating liquid is conducted at a heating temperature of 170° C.-270° C.

16. The method according to claim 14, wherein the removing of the second removal target region removes the entirety of the second removal target region in the thickness direction of the second removal target region.

17. The method according to claim 14, wherein the removing of the second removal target region removes only the portion of the second removal target region which faces the color filter layer in the thickness direction of the second removal target region.

18. The method according to claim 14, wherein the color filters, the transparent resin layer, and the partition wall are formed such that formulas (1)-(5) are satisfied:
200≤A≤700 (1)
0<B≤200 (2)
A+B−200≤C≤A+B+200 (3)
D≥90 (4)
E≤200 (5)
where A is a thickness, in nm, of the color filter of the first color, B is a thickness, in nm, of the transparent resin layer, C is a thickness, in nm, of a color filter of a color other than the first color, D is a visible light transmittance, in %, of the transparent resin layer, and E is a dimension in a width direction, in nm, of the partition wall.

19. The method according to claim 18, wherein the color filters of the multiple colors are formed such that formula (7) is satisfied:
A−200≤C≤A+200 (7).

20. The method according to claim 18, wherein the color filters of the multiple colors are formed such that the color filter of the first color occupies a largest area among the color filters of the multiple colors.
